(19) United States
(12) Patent Application Publication
(10) Pub. No.: US 2008/0223438 A1
(43) Pub. Date: Sep. 18, 2008

(54) Systems and methods for improving luminescent concentrator performance

(75) Inventors: Xiao-Dong Xiang, Danville, CA (US); Wei Shan, Fremont, CA (US)

Correspondence Address: BUCHANAN, INGERSOLL & ROONEY PC, POST OFFICE BOX 1404, ALEXANDRIA, VA, 22313-1404, US

(73) Assignee: Intematix Corporation, Fremont, CA (US)

(21) Appl. No.: 11/975,071

(22) Filed: Oct. 17, 2007

Related U.S. Application Data
(60) Provisional application No. 60/853,369, filed on Oct. 19, 2006.

(51) Int. Cl. H01L 31/0232; G02F 1/35

(52) U.S. Cl. 136/257; 136/259; 250/227.23

(57) ABSTRACT

Disclosed herein are systems and methods for improving the performance of a luminescent concentrator. Performance may be enhanced by incorporating a reflector capable of blocking re-emitted photons from the luminescent material used to make frequency down conversion with a narrow reflection band, while allowing broad transmission of incident sunlight. The reflection band of the reflector that spectrally matches to the bandwidth of re-emission from the luminescent material acts as a luminescence cavity to prevent the outgoing re-emission that cannot be waveguided by total internal reflection to the photovoltaic device(s) located at the side edges of the concentrator. Further embodiments include using inorganic phosphors specifically as luminescent materials

### REFERENCE TO RELATED APPLICATIONS

This application claims benefit of U.S. Patent Application No. 60/853,369, filed Oct. 19, 2006, titled “Methods for performance improvement of luminescent concentrator.” U.S. Patent Application No. 60/853,369 is incorporated herein in its entirety.

### BACKGROUND OF THE INVENTION

1. Field of the Invention

Embodiments of the present invention are directed to the field of photovoltaics (PV), a technology that converts solar energy directly into electrical energy. The field of the invention is specifically directed to a luminescent concentrator device that converts solar energy into electricity.

2. Description of the Related Art

The concept of a luminescent concentrator (LC) for solar energy conversion was introduced in the 1970s to overcome the spectral loss of various solar cells. Spectral loss, in general, is a phenomenon where the shorter the wavelength of the incident light, the lower photocurrent generated in the solar cell. This is primarily because the electrons generated by short-wavelength incident light have a higher concentration at the vicinity of the surface, and therefore a larger probability of loss before they can diffuse to p-n junction region. Loss can be due to various recombination mechanisms such as surface recombination, compared to that generated by longer wavelength photons.

In the earlier version of these concentrators, organic dye molecules dispersed and doped in a transparent glass or plastic substrate with its refractive index larger than air were used to absorb short-wavelength photons of incident sunlight, and to re-emit those photons at longer wavelengths. This is known as frequency down conversion, where the solar cells have better spectral response in terms of quantum efficiency, and therefore higher energy conversion efficiency can be achieved. Since the luminescent materials emit photons in all directions, the transparent sheet of higher refractive index acts as a waveguided collector, trapping the re-emitted light that strikes at the surface of the plate with an incident angle larger than the critical angle for total internal reflection. This ensures the collection of the trapped light piping down from one point to another and undergoing the internal reflection, ending at the edges of the underlying solar cells (J. Javetski, Electronics, 52, 105(1979); H. J. Hovel et al., Solar Energy Materials, 2, 19(1979); A. H. Zewail et al., U.S. Pat. No. 4,227,939). Later on, the idea was expanded to use inorganic semiconductor quantum dots (K. W. J. Barnham, U.S. Pat. No. 6,4763,120, and references therein) and nanostructured composite materials (M. Buretea et al., US Pat. Application Publication US2004/0095658) as luminescent materials.

Compared to the other types of solar concentrators, LC has several advantages that include: (i) no tracking of sun movement is required because the luminescent materials absorb incident light at any angle; (ii) much less heating is generated in the edge-mounted solar cells because the heat from the excess energy of the short-wavelength photons is dissipated over the entire area of the concentrator; (iii) it works under both direct and diffuse sunlight conditions, and (iv) concentration factor can be easily scaled up by increasing the area of the collector over its given thickness. However, Snell's law states that a fraction of re-emitted luminescence, with a probability of typically 25˜30% depending on the difference between the refractive indexes of the collector and the air, is to escape out of the transparent substrate relying on total internal reflection when its angle of incidence from the medium to the interface with air is smaller than the critical angle. The performance of a LC can be severely impaired by this so-called critical-angle loss alone. One way to minimize this loss is to reduce the critical angle for total internal reflection via geometric improvement. But the law of physics dictates that results in very limited loss reduction. For this reason, it is extremely important to find other methods to resolve this fundamental problem therefore to improve the performance of an LC.

### SUMMARY OF THE INVENTION

Embodiments of the present invention are directed to systems and methods for improving the performance of a luminescent concentrator. The performance of a luminescent concentrator according this invention may be greatly improved by incorporating a reflector capable of blocking re-emitted photons by the luminescent material used to make frequency down conversion with a narrow reflection band while allowing broad transmission of incident sunlight. The reflection band of the reflector that spectrally matches to the bandwidth of re-emission from the luminescent material acts as a luminescence cavity to prevent the outgoing re-emission that cannot be “piped down” (or waveguided) by total internal reflection to the side edges from being lost, therefore minimizing the critical-angle loss and increasing the output light intensity at the edge-mounted solar cells. Further embodiments include using inorganic phosphors specifically as luminescent materials to meet the stringent requirements of high quantum efficiency and stability in terms of chemical and thermal properties for a luminescent concentrator system.

In one embodiment of the present invention, the luminescent concentrator (LC) comprises a luminescent substrate having top and bottom surfaces, the top surface facing the incident solar radiation, wherein the substrate contains a phosphor to absorb photons of a higher energy from the solar radiation, and to re-emit lower energy photons isotropically. The LC further comprises a band-blocking reflector covering at least one of the surfaces of the substrate, where the reflector reflects back into the substrate lower energy luminescent photons that are not totally internally reflected by the top and bottom surfaces of the substrate. The LC also has a photovoltaic cell positioned adjacent to at least one side edge of the luminescent concentrator to receive the waveguided photons and to convert those photons into electricity. The band-blocking reflector may be a reflective diffraction grating, which in turn may be a volume Bragg grating (VBG).

In alternative embodiments, the LC may contain two different types of photovoltaic cells: in particular, a first photovoltaic cell having a lower band-gap, the first cell positioned adjacent to a first side edge of the concentrator to collect solar flux not absorbed by the luminescent substrate; and a second photovoltaic cell having a higher band-gap than the first photovoltaic cell, the second cell positioned adjacent to a second side edge of the concentrator for receiving totally internally reflected photons from the luminescent substrate. A variation of this embodiment is that the second photovoltaic cell having a higher band-gap than the first photovoltaic cell, the second cell positioned adjacent to the bottom surface of the substrate.

Methods of generating electricity from solar radiation include providing a phosphor to absorb higher energy photons from solar radiation incident on a surface of a luminescent substrate containing the phosphor; isotropically re-emitting from the phosphor longer wavelength photons in directions greater than, and less than and equal to the critical angle for total internal reflection from a band-blocking reflector covering at least one surface of the luminescent substrate; total internally reflecting the re-emitted photons with angles of incidence less than or equal to the critical angle, and waveguiding those photons through the luminescent substrate to a photovoltaic cell positioned adjacent to at least one side edge of the substrate; and reflecting the re-emitted photons with angles of incidence greater than the critical angle off of the band-blocking reflector back into the substrate, such that these photons are not transmitted out of the substrate.

### BRIEF DESCRIPTION OF THE DRAWINGS

FIG. 1 is an illustration of luminescent concentrator using band-blocking reflector;

FIG. 2 is a graph of reflectivity profile of band-blocking reflector, as well as absorption and emission profiles of a luminescent material; the spectra are vertically displaced for clarity;

FIG. 3 is an illustration of using angular-multiplexed narrowband reflective grating to minimize critical-angle loss in luminescent concentrator system;

FIG. 4 shows an example of available insolation at luminescent materials after sunlight passing through the narrowband rejection filter that is placed on top of an LC substrate;

FIG. 5 shows an example of available spectral irradiance at PV cells in an LC device; the grayed area includes both re-emitted luminescence and unabsorbed portion of the sunlight;

FIG. 6A is a schematic illustration of using a second, edge-mounted PV cell with a smaller band gap to capture the portion of sunlight that is not absorbed by the luminescent material; and

FIG. 6B is a schematic illustration of using a second, bottom-mounted PV cell with a smaller band gap to capture the portion of sunlight that is not absorbed by the luminescent material.

### DETAILED DESCRIPTION OF THE INVENTION

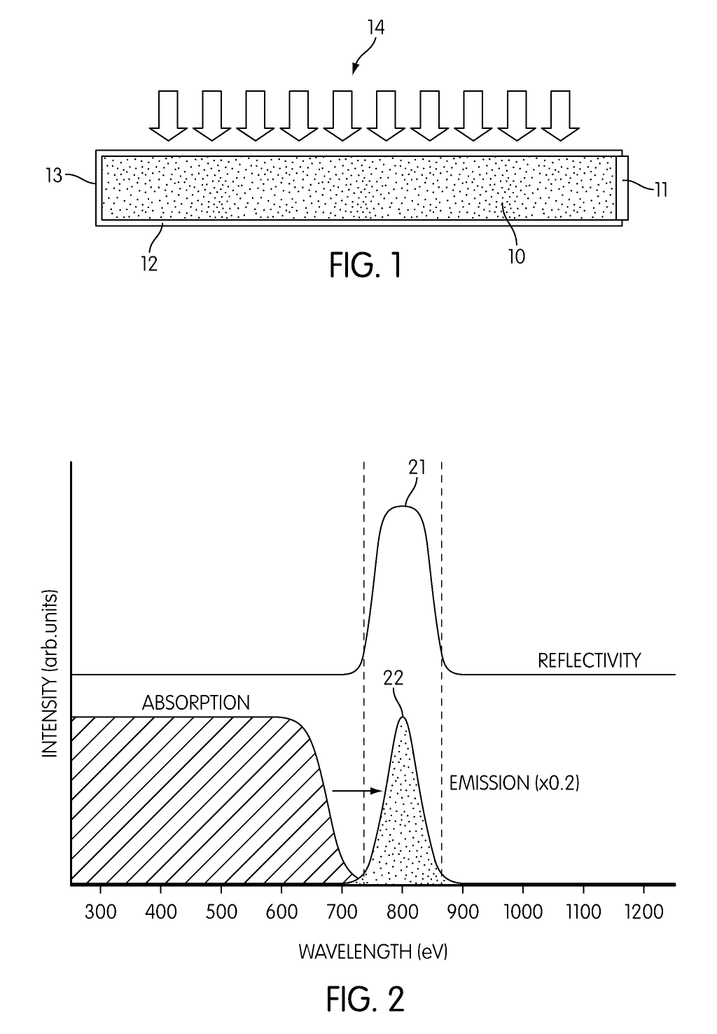

Disclosed herein are systems and methods for improving luminescent contractor performance. Referring to FIG. 1, a luminescent concentrator (LC) device may comprise a transparent substrate 10, a photovoltaic (PV) cell 11 attached to one of its side edges (or, in the case of an array of PV cells, to more than one side edge), and a band-blocking reflector 12 which may cover the top and bottom surfaces of the transparent substrate 10, as well as the side edge(s) 13 where no cells have been attached. In this case, the orientation of the LC is such that the “top surface” is that which faces the incident solar radiation. The coverage on the opposite surface (or “bottom” surface) and the side edges may be replaced by a mirrored coating.

The transparent substrate 10 may be made of optically clear matrix such as but not limited to glass or plastic, the matrix containing one or more luminescent materials. When sunlight 14 is incident on the top of the substrate, properly selected luminescent materials in the matrix absorb nearly all short-wavelength photons from the sunlight and re-emit them as luminescence in longer wavelengths. This emission from the luminescent material is isotropic; that is to say, some photons in shallow angles relative to the top and bottom surfaces of the substrate, such that they are totally internally reflected, and some photons at angles more toward the normal to the surface, such that the would transmitted out that surface were it not for the reflector 12.

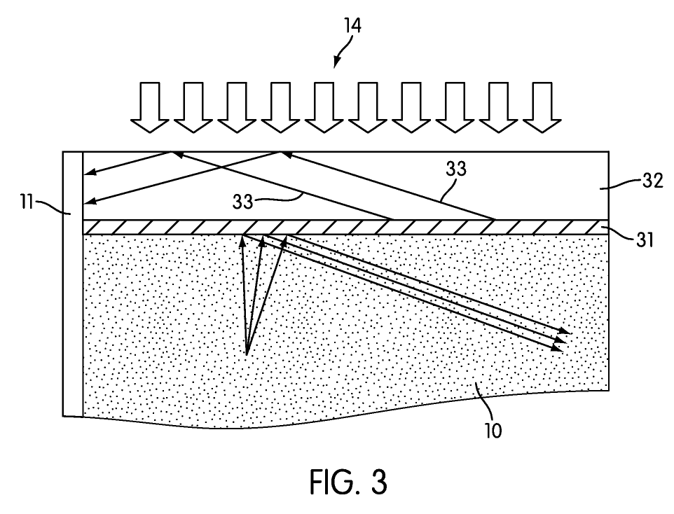

The relationship between the reflectivity band of the reflector, and the emission band of the phosphor, is shown in FIG. 2. Here, the reflector has a narrow reflection band 21 that substantially matches the emission bandwidth of luminescence 22, so that the phosphor-emitted, luminescent photons that would have escaped because they were not totally internally reflected. This keeps the re-emitted, longer wavelength photons inside the transparent substrate 10 until they are able to reach PV cell 11 to generate electricity.

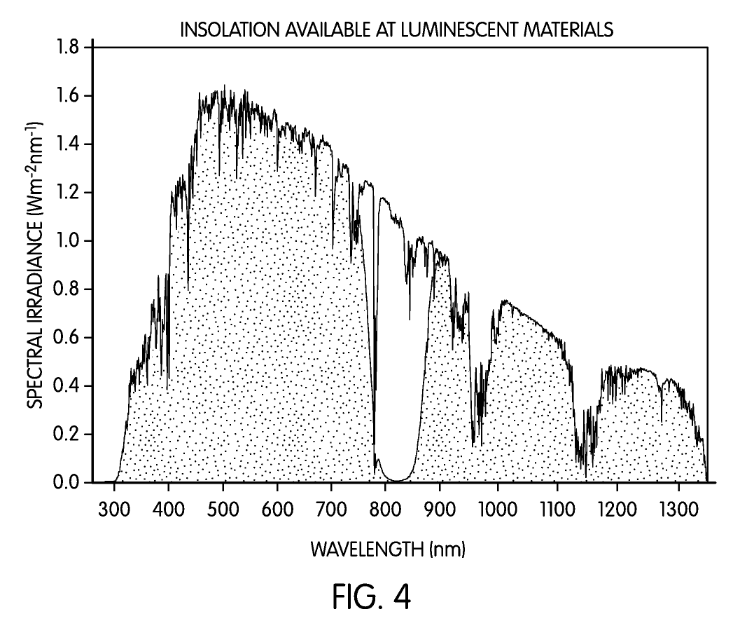

In one embodiment of the present invention, the band-blocking reflector 13 may be a reflective diffraction grating, as shown in FIG. 3. Such a grating is a collection of reflecting elements that are separated by a distance comparable to the wavelengths of interest (called the “grating constant”). The elements may be a periodic thickness variation (referred to as “surface relief”) of a transparent material, or a periodic refractive-index variation (volume) within a flat film formed along one dimension. A beam of white light incident on a grating is separated into its component colors upon diffraction, with each color diffracted along a different direction, providing spatial distribution in wavelength for the light.

When the thickness of a grating significantly exceeds the fundamental fringe period recorded in it the grating is said to operate in the Bragg diffraction regime, and is referred to as a volume Bragg grating (VBG). The extended volume of its medium serves to suppress (or “filter out”) all but the first diffraction order in reconstruction, and therefore the efficiency of the grating is very high. The VBG may be holographically produced using two unit amplitude plane waves of common wavelength that are incident on a photosensitive medium making angles with the surface normal. The arrangement of incidence on the same side of the photosensitive medium records a transmission hologram, whereas incidence from opposite sides of the medium forms a reflection hologram. A VBG is considered to be a very useful spectral as well as angular selector, having highly adjustable parameters. Angles of incidence and diffraction, central wavelength, and spectral as well as angular widths may be properly chosen by varying the grating thickness, period of refractive index modulation, and grating vector orientation.

The physics of volume diffraction thus endows a VBG with a selectivity property that may be exploited. In one embodiment, the VBG multiplexes a number of holograms that are stored within the same physical volume, which may then diffract light incident from different angles independently. This greatly enhances the overall capabilities of the volume grating, allowing it to accept light incident from a wide range of angles and diffract it to the same location.

A band-blocking reflector may be made by recording several holograms angularly multiplexed within the same physical volume of grating, and may be readily integrated into an LC device. The holograms satisfy Bragg condition and their spectral bandwidth match the re-emission from luminescent material used in the LC. Referring to FIG. 3, the optics of the reflective VBG 31 diverts the outgoing, re-emitted photons of smaller-than-critical-angle into an angle relative to the surface normal much larger than that required for total internal reflection, when such photons strike the angularly-multiplexed reflective diffraction grating. In this way, the critical-angle loss may be minimized and nearly all the re-radiated photons by the luminescent material may be collected by edge-mounted PV cells.

By the nature of the reflective grating, a fraction of the sunlight in the spectral region of its reflection band may also be diffracted away. However, the large diffraction angle ensures that diffracted portion of sunlight can be “piped” by the high refractive-index glass substrate 32 of the grating, down the stretch via total internal reflection to the LC side edges, as illustrated by FIG. 3. The waveguided rays are shown by reference numeral 33 in FIG. 3. This accomplishes the goal of delivering an enhanced number of photons to the PV cell located at one end of the grating.

In another embodiment, the band-blocking reflector may be a narrowband rejection filter comprising a multilayer dielectric coating. Such a filter freely transmits all radiation incident upon it except in the one, narrow spectral region in which the radiation is reflected. The high-reflective filter may be constructed using many layers with alternating high and low refractive index materials that are transparent to solar spectrum. By choosing the proper optical thickness of each layer, the spectral region, bandwidth, and reflectivity may be well controlled by the constructive interference between different reflected amplitudes. With its rejection band matching the frequency down converted re-emission from the luminescent material, the filter covering the luminescent substrate reflects back those re-radiated photons unable to be internally reflected, keeping them confined within the LC structure, eventually to be absorbed by the PV cell(s) positioned adjacent to at least one edge of the reflector.

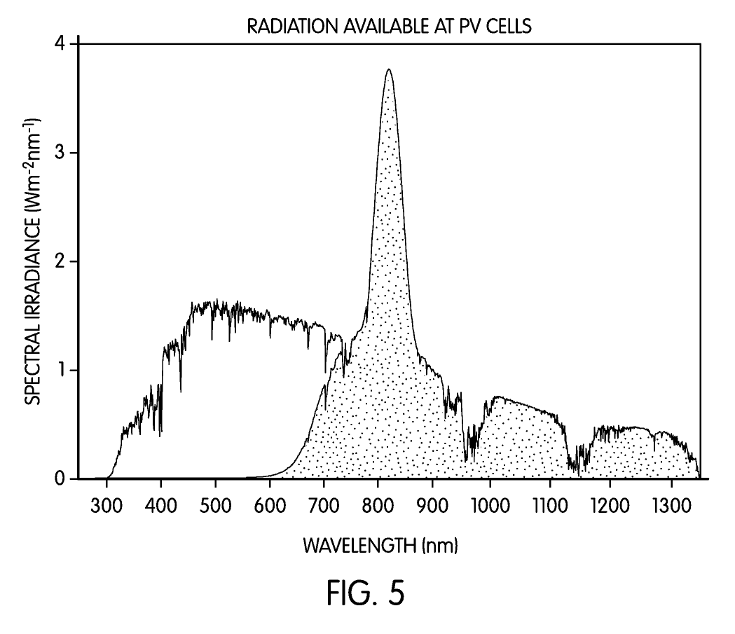

It is worthy noting that such a high-reflection band filter also blocks a small fraction of incident sunlight of the same spectral breadth. This concept is illustrated in FIG. 4, where the grayed area under the AM1.5G solar irradiance spectrum represents the insolation available after the sunlight passes through a narrowband reflective filter with a 120-nm rejection band centered at 800 nm. It is about 90% of the total irradiance of Air Mass 1.5 Global (AM1.5G), equivalent to Air Mass 1.5 Direct (AM1.5D) radiation. Conventional geometric-optics based solar concentrators work efficiently only under direct radiation.

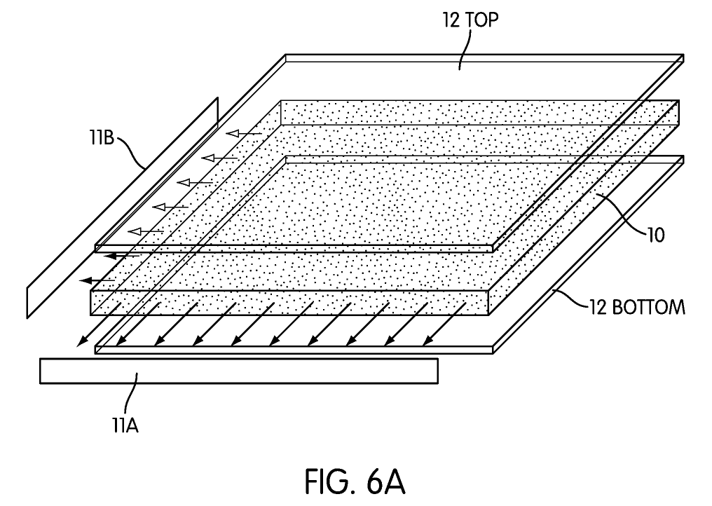

In a further embodiment, the luminescent materials may be an inorganic phosphor. The compounds are rare-earth element (the “activator”) doped crystals which emission wavelength may be tuned by the host materials and species of dopants as a result of electron-phonon (lattice vibration) interactions associated with the local crystal field. Their high brightness in emission, excellent chemical stability, high quantum efficiency, and amenability to volume production make phosphors more robust and reliable materials relative to other luminescent materials, such as organic dyes. By using an proper phosphor that has a broad absorption of nearly all the light of a wavelength smaller (photon energy larger) and a relatively narrow emission at wavelengths longer (photon energy smaller) than its absorption edge in an LC, the spectral irradiance at a given PV cell may be altered. Referring to FIG. 5, this is done to optimize the solar energy conversion efficiency of the system by matching the spectral response maximum of the cell, and adjusting the surface area to thickness ratio of the luminescent substrate (and therefore the concentration factor).

A number of phosphors with different absorption and emission bands may be placed in the same substrate to achieve the so-called “photon cascade effect.” In this configuration, each phosphor absorbs from a certain portion of solar spectrum. The emission from a phosphor at the higher end of the energy spectrum is absorbed by a phosphor corresponding to a lower absorption band, whose emission in turn is absorbed by a third phosphor that emits photons at an even longer wavelength, and so forth. Photon cascading requires that the quantum efficiency of frequency down conversion for those phosphors is very high, preferably close to unity. The critical-angle loss must be also minimized for this photon cascade arrangement, and thus an optimized configuration requires either the use of several reflectors each with the appropriate rejection band, or the use of a reflector with several rejection bands. Such complexity may be avoided with a set of phosphors placed in the same luminescent substrate, each phosphor absorbing a different part of the solar flux, and re-emitting luminescence in a substantially similar wavelength region. The latter is accomplished by doping a common activator into different host crystals.

As luminescent materials, a phosphor or a plurality of phosphors may be uniformly doped or dispersed into either a portion, or all, of the volume of a luminescent substrate. Alternatively, the luminescent materials may be applied as a ribbon layer on either the top or between the substrate and the reflective optics, or at the bottom of the substrate, again between the substrate and any mirror coating. In yet another embodiment, the luminescent materials may be sandwiched between two transparent sheets to form a luminescent substrate. The concentration of the phosphor(s) in the luminescent substrate is high enough to have the desired optical density such that the phosphors may absorb the incident sunlight as completely as possible, each phosphor in the set absorbing substantially completely within its corresponding absorption band.

Because there is always a Stokes shift between absorption and emission bands in photon energy, it is nearly impossible to absorb all the solar flux within an entire working wavelength range of a PV cell (being used as the solar receiver in a LC device) with one or more phosphors without leaving some solar irradiance unused. In order to fully utilize the solar irradiance, PV cells of two different band gaps in an LC may be deployed to increase the solar power output from the concentrator. This enhances the solar-energy conversion efficiency for the system to an even greater degree.

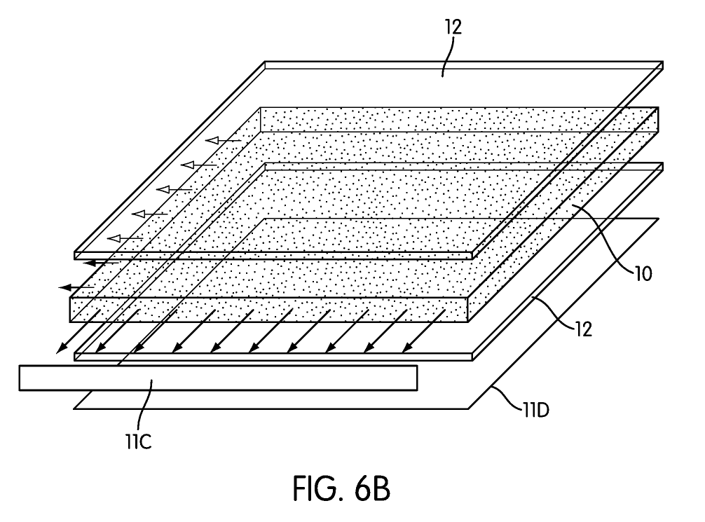

Referring to FIG. 6, higher band-gap PV cells such as, but not limited to, GaAs single-junction cell 11A may be used to convert primarily re-emitted photons from luminescent materials into electricity. Lower band-gap PV cells, such as Si or CuIn₁₋ₓGaₓSe₂ cells 11B, may be used to collect the solar flux that was not absorbed by the luminescent materials and the higher band-gap cells. The lower band-gap cells 11 C may be placed on the side edges not occupied by the higher band-gap cells if the bottom surface of an LC substrate is mirror coated (FIG. 6A), and the cells 11D may be attached to the bottom surface directly if a band-blocking reflector is used to cover the bottom surface (FIG. 6B).

What is claimed is:

1. A luminescent concentrator (LC) comprising:
a luminescent substrate having top and bottom surfaces, the top surface adapted to face incident solar radiation, the substrate containing a phosphor to absorb photons of a higher energy from the solar radiation, and to emit lower energy photons isotropically;
a band-blocking reflector covering at least one of the surfaces of the substrate, the reflector being operative to reflect back into the substrate emitted lower energy luminescent photons that are not totally internally reflected by the top and bottom surfaces of the substrate; and
a photovoltaic cell positioned adjacent to at least one side edge of the luminescent substrate to receive the internally reflected photons and to convert those photons into electricity.

2. The luminescent concentrator of claim 1, wherein the band-blocking reflector is a reflective diffraction grating.

3. The luminescent concentrator of claim 1, wherein the band-blocking reflector is a volume Bragg grating (VBG).

4. The luminescent concentrator of claim 1, wherein the band-blocking reflector optionally covers a side edge of the luminescent substrate that is not positioned adjacent to a photovoltaic cell.

5. The luminescent concentrator of claim 1, wherein the absorption band of the phosphor in the luminescent substrate substantially matches the reflection band of the band-blocking reflector.

6. A luminescent concentrator (LC) comprising:
a luminescent substrate having top and bottom surfaces, the top surface adapted to face incident solar radiation, the substrate being responsive to the radiation and operative to emit photons;
a band-blocking reflector covering at least one of the surfaces of the substrate;
a first photovoltaic cell having a first band-gap, the first cell being positioned adjacent to a first side edge of the substrate to collect solar flux not absorbed by the luminescent substrate; and
a second photovoltaic cell having a second band-gap higher than that of the first photovoltaic cell, the second cell being positioned adjacent to a second side edge of the concentrator for receiving photons emitted by the luminescent substrate.

7. The luminescent concentrator of claim 6, wherein the band-blocking reflector is selected from the group consisting of a reflective diffraction grating and a volume Bragg grating.

8. A luminescent concentrator (LC) comprising:
a luminescent substrate having top and bottom surfaces, the top surface being adapted to face incident solar radiation;
a band-blocking reflector covering both the top and bottom surfaces of the substrate;
a first photovoltaic cell having a first band-gap, the first cell being positioned adjacent to at least one side edge of the substrate to collect solar flux not absorbed by the luminescent substrate; and
a second photovoltaic cell having a second band-gap higher than that of the first photovoltaic cell, the second cell being positioned adjacent to the bottom surface of the substrate.

9. The luminescent concentrator of claim 8, wherein the band-blocking reflector is selected from the group consisting of a reflective diffraction grating and a volume Bragg grating.

10. A method of generating electricity from solar radiation, the method comprising:
providing a phosphor to absorb higher energy photons from solar radiation incident on a surface of a luminescent substrate containing the phosphor;
isotropically re-emitting from the phosphor longer wavelength photons in directions greater than, and less than and equal to the critical angle for total internal reflection from a band-blocking reflector covering at least one surface of the luminescent substrate;
total internally reflecting the re-emitted photons with angles of incidence less than or equal to the critical angle, and waveguiding those photons through the luminescent substrate to a photovoltaic cell positioned adjacent to at least one side edge of the substrate; and
reflecting the re-emitted photons with angles of incidence greater than the critical angle off of the band-blocking reflector back into the substrate, such that these photons are not transmitted out of the substrate.
